(19) United States
(12) Patent Application Publication
(10) Pub. No.: US 2025/0198006 A1
(43) Pub. Date: Jun. 19, 2025

(54) Functional Coating With Improved Thermal Stress Properties

(71) Applicant: Vitro Flat Glass LLC, Cheswick, PA (US)

(72) Inventor: Patrick Fisher, Cheswick, PA (US)

(21) Appl. No.: 18/976,425

(22) Filed: Dec. 11, 2024

Related U.S. Application Data
(60) Provisional application No. 63/609,541, filed on Dec. 13, 2023.

(51) Int. Cl. C23C 28/04

(52) U.S. Cl. CPC C23C 28/04

(57) ABSTRACT

The invention is directed to a coated article having a functional layer over a substrate. The functional layer includes at least one stabilizing layer that reduces the occurrence of defects during heat treatment. The functional layer includes a base layer over the substrate, a first protective layer over the base layer, an optional first stabilizing layer, a transparent conductive oxide layer over the first stabilizing layer or first protective layer, an optional second stabilizing layer positioned over at least a portion of the transparent conductive oxide layer, and a second protective layer over at least a portion of the second stabilizing layer and/or the transparent conductive oxide layer. The first and/or second stabilizing layer can comprise zinc oxide, tin oxide, or combinations thereof. The base layer can include a first film formed from tin oxide in direct contact with the portion of the substrate.

### CROSS REFERENCE TO RELATED APPLICATION

This application claims the benefit of U.S. Provisional Application No. 63/609,541, filed Dec. 13, 2023, which is hereby incorporated by reference in its entirety.

### BACKGROUND OF THE INVENTION

### Field of the Invention

The invention relates to coated articles having improved thermal stress properties, and more particularly to coated articles having improved stability of the coating during heat treatment resulting in greater resistance to the initiation and outward growth of defects in the articles. The coated articles also have a low emissivity and neutral color.

### Description of Related Art

Transparent conductive oxides (“TCOs”) are applied to the substrate to provide the coated article with lower emissivity and lower sheet resistance. This makes TCOs particularly useful in electrodes (for example solar cells) or heating layers, activating glazing units, or screens. TCOs are usually applied by vacuum deposition techniques, such as magnetron sputtering vacuum deposition (“MSVD”). Generally, a thicker TCO layer provides a lower sheet resistance. The thickness of the TCO, however, impacts the color of the coated article. Therefore, there is a need to adjust the coloring effect caused by TCO layers. There is also a need to minimize the thickness of a TCO layer so as to minimize the impact the TCO has on the color of the coated article while still maintaining the required sheet resistance.

Coating stacks may corrode over time. To protect from this, protective overcoats can be applied to coatings. For example, titanium dioxide films disclosed in U.S. Pat. Nos. 4,716,086 and 4,786,563 are protective films that provide chemical resistance to a coating. Silicon oxide, disclosed in Canadian Patent Number 2,156,571, and aluminum oxide and silicon nitride disclosed in U.S. Pat. Nos. 5,425,861; 5,344,718; 5,376,455; 5,584,902; and 5,532,180; and in PCT International Patent Publication No. 95/29883 are also protective films that provide chemical resistance to a coating. This technology could be advanced by more chemically and/or mechanically durable protective overcoats.

After application of the various coatings to the substrate, the coated article is treated to a post-deposition process that can include heating or tempering, flash annealing, or passing an Eddy current through the transparent conductive oxide layer. During the post-deposition process, defects can form in the coatings. Upon heating of coated articles with solar control coatings, an undesirable haze can occur due to the changes in the optical properties and morphology of the layers of the solar control coating. Thus, there is a need for reducing the occurrence of defects during this post-deposition process. There is also a need for producing a solar control coating in which the absorption of the coating and/or the color of the coated article can be maintained before heating and after heating.

### SUMMARY OF THE INVENTION

In accordance with one embodiment, a coated article comprises a substrate comprising a first surface and a second surface opposite the first surface; and a coating applied over at least a portion of the first surface, the coating comprising: a base layer over at least a portion of the first surface; a first protective layer over at least a portion of the base layer; an optional first stabilizing layer over at least a portion of the first protective layer; a transparent conductive oxide layer over the first stabilizing layer or the first protective layer; an optional second stabilizing layer positioned over at least a portion of the transparent conductive oxide layer; and a second protective layer over at least a portion of the second stabilizing layer or the transparent conductive oxide layer. The base layer comprises a first film comprising tin oxide in direct contact with the portion of the first surface and at least one of the first stabilizing layer and the second stabilizing layer comprises zinc oxide, tin oxide, or a combination thereof. At least one of the first protective layer and the second protective layer can comprise titania, alumina, zinc oxide, tin oxide, zirconia, silica, or mixtures thereof. According to one embodiment, the at least one of the first protective layer and the second protective layer comprises silicon aluminum oxide and the at least one of the first stabilizing layer and the second stabilizing layer comprises zinc stannate.

At least one of the first stabilizing layer and the second stabilizing layer or both of the stabilizing layers have a thickness of greater than zero and less than or equal to 50 nm, a thickness of greater than zero and less than or equal to 20 nm, or a thickness of greater than zero and less than or equal to 10 nm.

The transparent conductive oxide layer can comprise one of tin-doped indium oxide (“ITO”), gallium-doped zinc oxide (“GZO”), indium-doped zinc oxide (“IZO”), magnesium-doped zinc oxide (“MZO”), fluorine-doped tin oxide (“FTO”), antimony-doped tin oxide (“ATO”), and/or aluminum-doped zinc oxide (“AZO”). According to one embodiment, the transparent conductive oxide layer can comprise tin-doped indium oxide (“ITO”).

In accordance with another embodiment, a coated article comprises a substrate comprising a first surface and a second surface opposite the first surface; and a coating applied over at least a portion of the first surface, the coating comprising: a base layer over at least a portion of the first surface; a first protective layer over the base layer; an optional first stabilizing layer over at least a portion of the first protective layer; a transparent conductive oxide layer over the first stabilizing layer or the first protective layer; an optional second stabilizing layer positioned over at least a portion of the transparent conductive oxide layer; and a second protective layer over the second stabilizing layer or the transparent conductive oxide layer. At least one of the first stabilizing layer and the second stabilizing layer has a thickness of greater than zero and at least one of the first stabilizing layer and the second stabilizing layer comprises zinc oxide, tin oxide, or a combination thereof. According to one embodiment, at least one of the first stabilizing layer and the second stabilizing layer comprises zinc stannate

At least one of the first stabilizing layer and the second stabilizing layer or both of the stabilizing layers have a thickness of greater than zero and less than or equal to 50 nm, a thickness of greater than zero and less than or equal to 20 nm, or a thickness of greater than zero and less than or equal to 10 nm.

According to one embodiment, the base layer can comprise a first film comprising tin oxide in direct contact with the portion of the first surface.

The invention is further described in the following numbered clauses:

Clause 1. A coated article comprising: a substrate comprising a first surface and a second surface opposite the first surface; and a coating applied over at least a portion of the first surface, the coating comprising: a base layer over at least a portion of the first surface; a first protective layer over at least a portion of the base layer; an optional first stabilizing layer over at least a portion of the first protective layer; a transparent conductive oxide layer over the first stabilizing layer or the first protective layer; an optional second stabilizing layer positioned over at least a portion of the transparent conductive oxide layer; and a second protective layer over at least a portion of the second stabilizing layer or the transparent conductive oxide layer, wherein at least one of the first stabilizing layer and the second stabilizing layer comprises zinc oxide, tin oxide, or a combination thereof.

Clause 2: The coated article of clause 1, wherein at least one of the first protective layer and the second protective layer comprises titania, alumina, zinc oxide, tin oxide, zirconia, silica, or mixtures thereof.

Clause 3: The coated article of clause 2, wherein the at least one of the first protective layer and the second protective layer comprises silicon aluminum oxide.

Clause 4: The coated article of any of clauses 1-3, wherein the at least one of the first stabilizing layer and the second stabilizing layer comprises zinc stannate.

Clause 5: The coated article of any of clauses 1-4, wherein the first stabilizing layer has a thickness of greater than zero and less than or equal to 20 nm.

Clause 6: The coated article of clause 4, wherein the first stabilizing layer has a thickness of greater than zero and less than or equal to 10 nm.

Clause 7: The coated article of any of clauses 1-6, wherein the second stabilizing layer has a thickness of greater than zero and less than or equal to 20 nm.

Clause 8: The coated article of clause 7, wherein the second stabilizing layer has a thickness of greater than zero and less than or equal to 10 nm.

Clause 9: The coated article of any of clauses 1-8, wherein the first stabilizing layer and the second stabilizing layer have a thickness of greater than zero.

Clause 10: The coated article of clause 9, wherein the first stabilizing layer and the second stabilizing layer have a thickness of greater than zero and less than or equal to 20 nm.

Clause 11: The coated article of clause 10, wherein the first stabilizing layer and the second stabilizing layer have a thickness of greater than zero and less than or equal to 10 nm.

Clause 12: The coated article of any of clauses 1-11, wherein the transparent conductive oxide layer comprises one of tin-doped indium oxide, gallium-doped zinc oxide, magnesium-doped zinc oxide, fluorine-doped tin oxide, antimony-doped tin oxide, and aluminum-doped zinc oxide.

Clause 13: The coated article of clause 12, wherein the transparent conductive oxide layer comprises tin-doped indium oxide.

Clause 14. The coated article of any of clauses 1-3, wherein the base layer comprises a first film comprising tin oxide in direct contact with the portion of the first surface.

Clause 15: A coated article comprising: a substrate comprising a first surface and a second surface opposite the first surface; and a coating applied over at least a portion of the first surface, the coating comprising: a base layer over at least a portion of the first surface; a first protective layer over the base layer; an optional first stabilizing layer over at least a portion of the first protective layer; a transparent conductive oxide layer over the first stabilizing layer or the first protective layer; an optional second stabilizing layer positioned over at least a portion of the transparent conductive oxide layer; and a second protective layer over the second stabilizing layer or the transparent conductive oxide layer; and wherein at least one of the first stabilizing layer and the second stabilizing layer has a thickness of greater than zero, wherein at least one of the first stabilizing layer and the second stabilizing layer comprises zinc oxide, tin oxide, or a combination thereof, and wherein at least one of the first protective layer and the second protective layer comprises titania, alumina, zinc oxide, tin oxide, zirconia, silica, or mixtures thereof.

Clause 16: The coated article of clause 15, wherein at least one of the first stabilizing layer and the second stabilizing layer has a thickness of greater than zero and less than or equal to 20 nm.

Clause 17: The coated article of claim 16, wherein at least one of the first stabilizing layer and the second stabilizing layer has a thickness of greater than zero and less than or equal to 10 nm.

Clause 18: The coated article of any of clauses 15-17, wherein the base layer comprises a first film comprising tin oxide in direct contact with the portion of the first surface.

Clause 19: The coated article of any of clauses 15-18, wherein at least one of the first stabilizing layer and the second stabilizing layer comprises zinc stannate.

Clause 20: The coated article of any of clauses 1-19, wherein the base layer comprises at least a second film positioned over and in direct contact with the first film such that the second film does not contact the substrate.

Clause 21. The coated article of clause 20, wherein the base layer comprises at least a third film positioned over and in direct contact with the second film.

Clause 22. A method of forming a coated article comprising providing a substrate and coating the substrate with the layers in accordance with any of clauses 1-21.

### BRIEF DESCRIPTION OF THE DRAWING(S)

For a more complete understanding of the presently disclosed invention, reference should now be made to the embodiments illustrated in greater detail in the accompanying drawings and described below by way of examples of the invention.

FIG. 1 is a side view (not to scale) of a substrate having a coating profile incorporating features of the invention.

FIG. 2 is a side view (not to scale) of a substrate having another coating profile incorporating features of the invention.

FIG. 3 is a side view (not to scale) of a substrate having another coating profile incorporating features of the invention.

FIG. 4 is a side view (not to scale) of a substrate having another coating profile incorporating features of the invention.

### DESCRIPTION OF THE INVENTION

Spatial or directional terms used herein, such as “left”, “right”, “upper”, “lower”, and the like, relate to the invention as it is shown in the drawing figures. It is to be understood that the invention can assume various alternative orientations and, accordingly, such terms are not to be considered as limiting.

Further, as used herein, all numbers expressing dimensions, physical characteristics, processing parameters, quantities of ingredients, reaction conditions, and the like, used in the specification and claims are to be understood as being modified in all instances by the term “about”. Accordingly, unless indicated to the contrary, the numerical values set forth in the following specification and claims may vary depending upon the desired properties sought to be obtained by the present invention. At the very least, and not as an attempt to limit the application of the doctrine of equivalents to the scope of the claims, each numerical value should at least be construed in light of the number of reported significant digits and by applying ordinary rounding techniques. Moreover, all ranges disclosed herein are to be understood to encompass the beginning and ending range values and any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more and ending with a maximum value of 10 or less, e.g., 1 to 3.3, 4.7 to 7.5, 5.5 to 10, and the like. Additionally, all documents, such as but not limited to, issued patents and patent applications, referred to herein are to be considered to be “incorporated by reference” in their entirety. Any reference to amounts, unless otherwise specified, is “by weight percent”. The term “film” refers to a region of a coating having a desired or selected composition. A “layer” comprises one or more “films”. A “coating” or “coating stack” is comprised of one or more “layers”. The terms “metal” and “metal oxide” are to be considered to include silicon and silica, respectively, as well as traditionally recognized metals and metal oxides, even though silicon is technically not a metal. By “not more than” is meant “less than or equal to”.

The term “over” means “farther from the substrate”. For example, a second layer located “over” a first layer means that the second layer is located farther from the substrate than the first layer. The second layer can be in direct contact with the first layer or one or more other layers can be located between the second layer and the first layer.

The term “visible light” means electromagnetic radiation having a wavelength in the range of 380 nm to 780 nm. The term “infrared radiation” means electromagnetic radiation having a wavelength in the range of greater than 780 nm to 100,000 nm. The term “ultraviolet radiation” means electromagnetic energy having a wavelength in the range of 100 nm to less than 380 nm.

The discussion of the invention herein may describe certain features as being “particularly” or “preferably” within certain limitations (e.g., “preferably”, “more preferably”, or “even more preferably”, within certain limitations). It is to be understood that the invention is not limited to these particular or preferred limitations but encompasses the entire scope of the disclosure.

The invention comprises, consists of, or consists essentially of, the following aspects of the invention, in any combination. Various aspects of the invention are illustrated in separate drawing figures. However, it is to be understood that this is simply for ease of illustration and discussion. In the practice of the invention, one or more aspects of the invention shown in one drawing figure can be combined with one or more aspects of the invention shown in one or more of the other drawing figures.

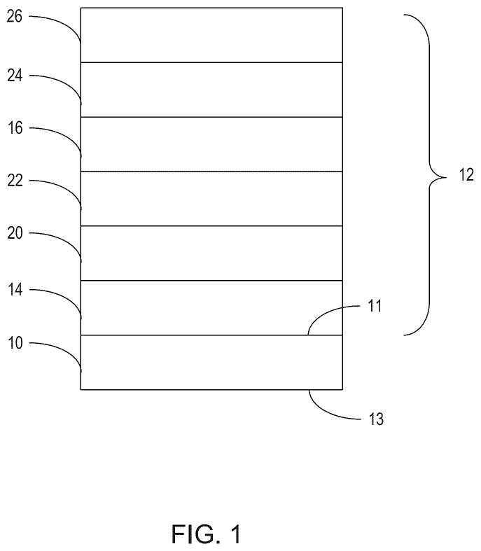

An exemplary article includes a substrate 10 having a first surface 11 and a coating 12 applied over at least a first portion of the first surface 11. The coating 12 includes a base layer 14 over the substrate 10 and a transparent conductive oxide 16 over the base layer 14 as shown in FIG. 1.

The article can be a window (such as an architectural window or an automotive window), a solar mirror, a solar cell, or an organic light-emitting diode. The coatings applied to the substrate 10 can provide low emissivity, low resistivity, scratch resistance, radio frequency attenuation or a desired color.

The substrate 10 can be transparent, translucent, or opaque to visible light. By “transparent” is meant having a visible light transmittance of greater than 0% up to 100%. Alternatively, the substrate 10 can be translucent or opaque. By “translucent” is meant allowing electromagnetic energy (e.g., visible light) to pass through but diffusing this energy such that objects on the side opposite the viewer are not clearly visible. By “opaque” is meant having a visible light transmittance of 0%.

The substrate 10 can be glass, plastic, or metal. Examples of suitable plastic substrates include acrylic polymers, such as polyacrylates; polyalkylmethacrylates, such as polymethylmethacrylates, polyethylmethacrylates, polypropylmethacrylates, and the like; polyurethanes; polycarbonates; polyalkylterephthalates, such as polyethyleneterephthalate (PET), polypropyleneterephthalates, polybutyleneterephthalates, and the like; polysiloxane-containing polymers; or copolymers of any monomers for preparing these, or any mixtures thereof); or glass substrates. Examples of suitable glass substrates include conventional soda-lime-silicate glass, borosilicate glass, or leaded glass. The glass can be clear glass. By “clear glass” is meant non-tinted or non-colored glass. Alternatively, the glass can be tinted or otherwise colored glass. The glass can be annealed or heat-treated glass. As used herein, the term “heat treated” means tempered or at least partially tempered. The glass can be of any type, such as conventional float glass, and can be of any composition having any optical properties, e.g., any value of visible transmission, ultraviolet transmission, infrared transmission, and/or total solar energy transmission. Examples of suitable metal substrates include aluminum or stainless steel.

The substrate 10 can have a high visible light transmission at a reference wavelength of 550 nanometers (nm) and a thickness of 2 millimeters. By “high visible light transmission” is meant visible light transmission at 550 nm of greater than or equal to 85%, such as greater than or equal to 87%, such as greater than or equal to 90%, such as greater than or equal to 91%, such as greater than or equal to 92%.

The base layer or underlayer 14 can be a single layer, a homogeneous layer, a gradient layer, a bi-layer, or can include a plurality of layers. By “homogeneous layer” is meant a layer in which the materials are randomly distributed throughout the coating. By “gradient layer” is meant a layer having two or more components, with the concentration of the components varying (continually changing or step change) as the distance from the substrate 12 changes.

The base layer 14 can include tin oxide. A tin target to sputter a tin oxide film may include one or more other materials to improve the sputtering characteristics of the zinc target. For example, the tin target can include up to 15 wt. %, such as up to 10 wt. %, such as up to 5 wt. %, of such a material. The resultant tin oxide layer would include a small percentage of an oxide of the added material, e.g., up to 15 wt. %, up to 10 wt. %, up to 9 wt. % of the material oxide. A layer deposited from a tin target having up to 10 wt. %, e.g., up to 5 wt. % of an additional material to enhance the sputtering characteristics of the zinc target is referred to herein as “a tin oxide layer” even though a small amount of the added material (or an oxide of the added material) may be present. An example of such a material is aluminum.

The base layer 14 can have a thickness in the range of 5 nm to 20 nm; preferably 7 nm to 17 nm; more preferably 8 nm to 15 nm; and most preferably 9 nm to 13 nm.

A first protective layer 20 can be positioned over or in direct contact with the base layer 14. The protective layer 20 may comprise titania, alumina, silica, zirconia, or a combination thereof. In one embodiment, the first protective layer 20 comprises a mixture of 70-90 weight percent silica, 10-20 weight percent alumina. The silica and the alumina in the protective layer can be fully oxidized. For example, the first protective layer 20 may comprise a mixture of titania and alumina. The first protective layer 20 may comprise 40-60 weight percent of alumina, and 60-40 weight percent of titania; 45-55 weight percent of alumina, and 55-45 weight percent of titania; 48-52 weight percent of alumina, and 52-48 weight percent of titania; 49-51 weight percent of alumina, and 51-49 weight percent of titania; or 50 weight percent of alumina, and 50 weight percent of titania.

The first protective layer 20 can have a thickness in the range of 20 nm to 40 nm; preferably 22 nm to 38 nm; more preferably 25 nm to 35 nm; most preferably 30 nm to 35 nm.

An optional first stabilizing layer 22 can be positioned over the first protective layer 20. The first stabilizing layer 22 can be zinc oxide, tin oxide, or a combination thereof. According to one embodiment, the optional first stabilizing layer 22 can include an alloy of zinc oxide and tin oxide. The alloy of zinc oxide and tin oxide can include 80 wt % to 99 wt % zinc and 20 wt % to 1 wt % tin; such as 85 wt % zinc to 99 wt % zinc and 15 wt % tin to 1 wt % tin; 90 wt % zinc to 99 wt % zinc and 10 wt % tin to 1 wt % tin; such as approximately 90 wt % zinc and 10 wt % tin. For example, the optional first stabilizing film 22 can include or can be a zinc stannate layer. By “zinc stannate” is meant a composition of the formula: Zn_{X}Sn_{1-X}O_{2-X} (Formula 1) where “x” varies in the range of greater than 0 to less than 1. For instance, “x” can be greater than 0 and can be any fraction or decimal between greater than 0 to less than 1. Zinc stannate has one or more of the forms of Formula 1 in a predominant amount. Zinc stannate in which x=2/3 is conventionally referred to as “Zn₂SO₄”. The alloy of zinc oxide and tin oxide can include 80 wt % to 99 wt % zinc and 20 wt % to 1 wt % tin; such as 85 wt % zinc to 99 wt % zinc and 15 wt % tin to 1 wt % tin; 90 wt % zinc to 99 wt % zinc and 10 wt % tin to 1 wt % tin; such as approximately 90 wt % zinc and 10 wt % tin. The optional first stabilizing layer 22 can alternatively comprise a metal oxide, nitride, or oxynitride. Examples of suitable metals for the stabilizing layer 22 include silicon, titanium, aluminum, zirconium, phosphorus, hafnium, niobium, zinc, bismuth, lead, indium, tin, tantalum alloys thereof, or mixtures thereof.

The first stabilizing layer 22 can have a thickness of greater than 0, and less than 20 nm, preferably less than 15 nm, more preferably less than 12 nm; most preferably less than 10 nm.

The transparent conductive oxide layer 16 is positioned over the base layer 14, over the protective layer 20, or in direct contact with the protective layer 20. The transparent conductive oxide layer 16 can be a single layer or can have multiple layers or regions. The transparent conductive oxide layer 16 has at least one conductive oxide layer. For example, the transparent conductive oxide layer 16 can include one or more metal oxide materials. For example, the transparent conductive oxide layer 16 can include one or more oxides of one or more of Zn, Fe, Mn, Al, Ce, Sn, Sb, Hf, Zr, Ni, Bi, Ti, Co, Cr, Si, In, or an alloy of two or more of these materials. For example, the transparent conductive oxide layer 16 can comprise tin oxide, zinc oxide, or aluminum oxide. For example, the transparent conductive oxide layer 16 can comprise tin oxide.

The transparent conductive oxide layer 16 can include one or more dopant materials, such as, but not limited to, F, In, Al, P, Cu, Mo, Ta, Ti, Ni, Nb, W, Ga, Mg, and/or Sb. For example, the dopant can be In, Ga, Al, or Mg. The dopant can be present in an amount less than 10 wt. %, such as less than 5 wt. %, such as less than 4 wt. %, such as less than 2 wt. %, such as less than 1 wt. %. The transparent conductive oxide layer 16 can be a doped metal oxide and thus comprise gallium-doped zinc oxide (“GZO”), aluminum-doped zinc oxide (“AZO”), indium-doped zinc oxide (“IZO”) magnesium-doped zinc oxide (“MZO”), fluorine-doped tin oxide (“FTO”), antimony-doped tin oxide (“ATO”), or tin-doped indium oxide (“ITO”). In one example, the transparent conductive oxide layer 14 comprises ITO.

The transparent conductive oxide layer 16 can have a thickness in the range of 100 nm to 160 nm; preferably 110 nm to 150 nm; more preferably 120 nm to 140 nm; most preferably 125 nm to 135 nm.

For example, when the transparent conductive oxide layer 16 is tin-doped indium oxide the thickness is in the range of 100 nm to 160 nm; preferably 110 nm to 150 nm; more preferably 120 nm to 140 nm; most preferably 125 nm to 135 nm.

An optional second stabilizing layer 24 can be positioned over the transparent conductive oxide layer 16. The optional second stabilizing layer 24 can be zinc oxide, tin oxide, or a combination thereof. According to one embodiment, the optional second stabilizing layer 24 can include an alloy of zinc oxide and tin oxide. For example, the optional second stabilizing layer 24 can include or can be a zinc stannate layer. The optional second stabilizing layer 24 can alternatively comprise a metal oxide, nitride, or oxynitride. Examples of suitable metals for the second stabilizing layer 24 include silicon, titanium, aluminum, zirconium, phosphorus, hafnium, niobium, zinc, bismuth, lead, indium, tin, tantalum alloys thereof, or mixtures thereof.

The second stabilizing layer 24 can have a thickness of greater than 0, and less than 20 nm, preferably less than 15 nm, more preferably less than 12 nm; most preferably less than 10 nm.

A second protective layer 26 can be positioned over or in direct contact with the transparent conductive oxide layer 16; or over or in direct contact with the second stabilizing layer 24. The second protective layer 26 may comprise titania, alumina, silica, zirconia, or a combination thereof. In one embodiment, the second protective layer 26 comprises a mixture of 70-90 weight percent silica, 10-20 weight percent alumina. For example, the second protective layer 26 can comprise a mixture of titania and alumina. The second protective layer 26 may comprise 40-60 weight percent of alumina, and 60-40 weight percent of titania; 45-55 weight percent of alumina, and 55-45 weight percent of titania; 48-52 weight percent of alumina, and 52-48 weight percent of titania; 49-51 weight percent of alumina, and 51-49 weight percent of titania; or 50 weight percent of alumina, and 50 weight percent of titania.

The second protective layer 26 can have a thickness in the range of 40 nm to 60 nm; preferably 42 nm to 58 nm; more preferably 45 nm to 55 nm; most preferably 50 nm to 55 nm.

According to one example, as shown in FIG. 1, the article can be a glass substrate 10 having a first surface 11. A coating 12 is located over the first surface 11. The coating 12 includes a base layer 14 over the glass substrate 10. The base layer 14 can comprise tin or tin oxide. A first protective layer 20 can be positioned over the base layer 14. The first protective layer 20 can comprise 70-90 weight percent silica, 10-20 weight percent alumina. An optional first stabilizing layer 22 can be positioned over or in direct contact with the first protective layer 20. The first stabilizing layer 22 can comprise zinc stannate. A transparent conductive oxide layer 16 can be over the first protective layer 20 or over or in direct contact with the first stabilizing layer 22. The transparent conductive oxide layer 16 can be ITO. An optional second stabilizing layer 24 can be over or in direct contact with the transparent conductive oxide layer 16. The second stabilizing layer 24 can comprise zinc stannate. A second protective layer 26 can be over or in direct contact with the transparent conductive oxide layer 16, or over or in direct contact with the second stabilizing layer 24 (if present). The second protective layer can comprise 70-90 weight percent silica, 10-20 weight percent alumina.

The optional first 22 and/or second 24 (described above) stabilizing layer reduces the susceptibility of the initiation and growth of defects in the coating that extend outward from other defects.

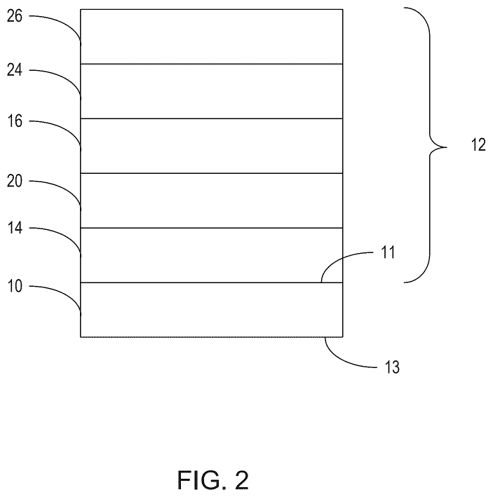

Referring to FIG. 2, there is shown another example of a substrate 10 having a coating profile in accordance with an embodiment of the invention. The substrate 10 has a first surface 11 and a second surface 13 opposite the first surface 11. A coating 12 is applied over at least a portion of the first surface 11. The coating 12 includes a base layer 14 over at least a portion of the first surface 11, a first protective layer 20 over at least a portion of the base layer 14, a transparent conductive oxide layer 16 over the first protective layer 20, a stabilizing layer, such as a “second” stabilizing layer 24 positioned over at least a portion of the transparent conductive oxide layer 16, and a second protective layer 26 over at least a portion of the second stabilizing layer 24. This example differs from the example shown in FIG. 1 in that the “first” stabilizing layer 22 is omitted. The second stabilizing layer 24 can comprise zinc oxide, tin oxide, or a combination thereof.

Optical design software can be used to determine the thickness of the layers. An example of a suitable optical modeling software is FILM STAR. Ideally, one strives to have a color having a transmitted a* in the range of −5 and +1 and a b* in the range of −3 and +3; and/or a reflected a* in the range of −4 and +1, and a reflected b* in the range of −6 and +3. Some variability is acceptable in this color. To obtain the desired color, one changes the thickness of the base layer or underlayer 14, first protective layer 20, (optional) first stabilizing layer 22, transparent conductive oxide layer 16, (optional) second stabilizing layer 24, and second protective layer 26 to obtain the desired color for the identified transparent conductive oxide and thickness of the transparent conductive oxide, wherein the thickness remains within the ranges provided in this specification.

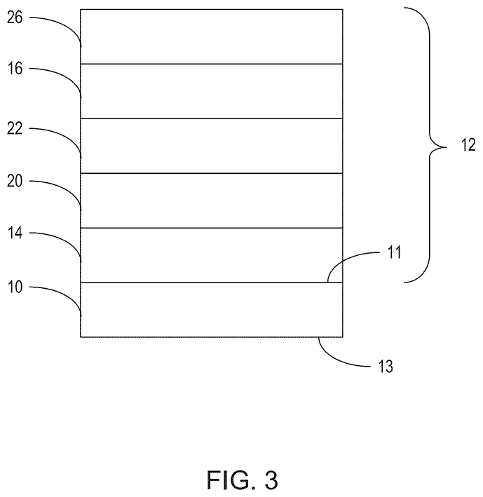

Reference is now made to FIG. 3, which illustrates another embodiment of a coated article. The coated article includes a substrate 10 having a first surface 11 and a second surface 13 opposite the first surface 11. A coating 12 is applied over at least a portion of the first surface 11. The coating includes a base layer 14 over at least a portion of the first surface 11, a first protective layer 20 over at least a portion of the base layer 14, a stabilizing layer, such as a “first” stabilizing layer 22, positioned over at least a portion of the first protective layer 20. A transparent conductive oxide layer 16 is positioned over the first stabilizing layer 22 and a second protective layer 26 is positioned over at least a portion of the transparent conductive oxide layer 16. The base layer 14 can comprise tin oxide over or in direct contact with the portion of the first surface 11. At least one of the first protective layer 20 and the second protective layer 26 comprises titania, alumina, zinc oxide, tin oxide, zirconia, silica, or mixtures thereof. According to one embodiment, the at least one of the first protective layer 20 and the second protective layer 26 can comprise a mixture of titania and alumina. The first stabilizing layer 22 can comprise zinc oxide, tin oxide, or a combination thereof. According to one embodiment, the second stabilizing layer 22 can comprise zinc stannate. The first stabilizing layer 22 has a thickness of greater than zero and less than or equal to 20 nm, greater than zero and less than or equal to 15 nm, or a thickness of greater than zero and less than or equal to 10 nm. As discussed above, the transparent conductive oxide layer 16 comprises one of indium-doped tin oxide, gallium-doped zinc oxide, aluminum-doped zinc oxide, magnesium-doped-zinc oxide, antimony-doped tin oxide, fluorine-doped tin oxide, or tin-doped indium oxide. According to one embodiment, the transparent conductive oxide layer 16 comprises tin-doped indium oxide (“ITO”).

The base or underlayer 14 may be a tin oxide film where tin is substantially the only metal in the base or underlayer 14. The tin oxide film base 14 can comprise a total thickness of from 5 nm to 45 nm. According to one embodiment, the base layer 14 can have a thickness, as deposited, of approximately 10.5 nm, but once heated, some of the tin oxide diffuses away and the thickness is approximately 8.5 nm.

The tin oxide can be deposited in an oxygen (O2) environment from a tin target or from a tin target that includes other materials to improve the sputtering characteristics of the target. For example, the O2 flow rate (i.e., concentration of O2 in the atmosphere for the chamber where the material is being deposited) can be up to 80% O2, such as 80% O2, 75% O2, or 70% O2. The remainder of the atmosphere can be an inert gas, such as argon. The tin oxide can be obtained from magnetron sputtering vacuum deposition from a target of tin or a target of tin and zinc. For example, the tin target can include a small amount (e.g., up to 20 wt. %, up to 15 wt. %, up to 10 wt. %, or up to 5 wt. %) of zinc. In which case, the resultant tin oxide film would include a small percentage of zinc oxide, e.g., up to 20 wt. % zinc oxide, e.g., up to 10 wt. % zinc oxide, e.g., up to 5 wt. % zinc oxide. A coating layer deposited from a tin target having up to from 0 wt. % to 20 wt. % zinc is referred to herein as “a tin oxide film”. As stated above, base layer 14 can be a tin oxide film where tin is substantially the only metal in the film. As used herein, “substantially free” means that the tin oxide film contains less than 0.5 wt. % of additional metals other than tin. The tin oxide film may include 80 wt. % tin oxide and 20 wt. % zinc oxide. The tin-zinc oxide film may include 90% tin oxide and 10 wt. % zinc oxide.

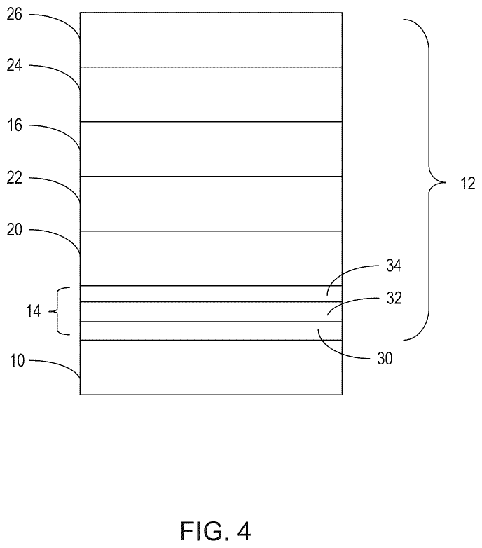

Referring to FIG. 4, the base or underlayer 14 can have a first film 30 and a second film 32, and/or a third film 34 in addition to the first protective layer 20, the optional first stabilizing layer 22, the transparent conductive oxide layer 16, the optional second stabilizing layer 24, and the second protective layer 26, as discussed above in relation to FIGS. 1-3.

It will be readily appreciated by those skilled in the art that modification may be made to the invention without departing from the concepts disclosed in the foregoing description. Accordingly, the particular embodiments described in detail herein are illustrative only and are not limiting to the scope of the invention, which is to be given the full breadth of the appended claims and any and all equivalents thereof.

The invention claimed is:

1. A coated article comprising:
a substrate comprising a first surface and a second surface opposite the first surface; and
a coating applied over at least a portion of the first surface, the coating comprising:
a base layer over at least a portion of the first surface;
a first protective layer over at least a portion of the base layer;
an optional first stabilizing layer over at least a portion of the first protective layer;
a transparent conductive oxide layer over the first stabilizing layer or the first protective layer;
an optional second stabilizing layer positioned over at least a portion of the transparent conductive oxide layer; and
a second protective layer over at least a portion of the second stabilizing layer or the transparent conductive oxide layer,
wherein at least one of the first stabilizing layer and the second stabilizing layer comprises zinc oxide, tin oxide, or a combination thereof.

2. The coated article of claim 1, wherein at least one of the first protective layers and the second protective layer comprises titania, alumina, zinc oxide, tin oxide, zirconia, silica, or mixtures thereof.

3. The coated article of claim 2, wherein the at least one of the first protective layer and the second protective layer comprises silicon aluminum oxide.

4. The coated article of claim 1, wherein the at least one of the first stabilizing layer and the second stabilizing layer comprises zinc stannate.

5. The coated article of claim 1, wherein the first stabilizing layer has a thickness of greater than zero and less than or equal to 20 nm.

6. The coated article of claim 5, wherein the first stabilizing layer has a thickness of greater than zero and less than or equal to 10 nm.

7. The coated article of claim 1, wherein the second stabilizing layer has a thickness of greater than zero and less than or equal to 20 nm.

8. The coated article of claim 7, wherein the second stabilizing layer has a thickness of greater than zero and less than or equal to 10 nm.

9. The coated article of claim 1, wherein the first stabilizing layer and the second stabilizing layer have a thickness of greater than zero.

10. The coated article of claim 9, wherein the first stabilizing layer and the second stabilizing layer have a thickness of greater than zero and less than or equal to 20 nm.

11. The coated article of claim 10, wherein the first stabilizing layer and the second stabilizing layer have a thickness of greater than zero and less than or equal to 10 nm.

12. The coated article of claim 1, wherein the transparent conductive oxide layer comprises one of tin-doped indium oxide, gallium-doped zinc oxide, magnesium-doped zinc oxide, fluorine-doped tin oxide, antimony-doped tin oxide, and aluminum-doped zinc oxide.

13. The coated article of claim 12, wherein the transparent conductive oxide layer comprises tin-doped indium oxide.

14. The coated article of claim 1, wherein the base layer comprises s first film comprising tin oxide in direct contact with the portion of the first surface.

15. A coated article comprising:
a substrate comprising a first surface and a second surface opposite the first surface; and
a coating applied over at least a portion of the first surface, the coating comprising:
a base layer over at least a portion of the first surface;
a first protective layer over the base layer;
an optional first stabilizing layer over at least a portion of the first protective layer;
a transparent conductive oxide layer over the first stabilizing layer or the first protective layer;
an optional second stabilizing layer positioned over at least a portion of the transparent conductive oxide layer; and
a second protective layer over the second stabilizing layer or the transparent conductive oxide layer; and
wherein at least one of the first stabilizing layer and the second stabilizing layer has a thickness of greater than zero, wherein at least one of the first stabilizing layer and the second stabilizing layer comprises zinc oxide, tin oxide, or a combination thereof, and wherein at least one of the first protective layer and the second protective layer comprises titania, alumina, zinc oxide, tin oxide, zirconia, silica, or mixtures thereof.

16. The coated article of claim 15, wherein at least one of the first stabilizing layer and the second stabilizing layer has a thickness of greater than zero and less than or equal to 20 nm.

17. The coated article of claim 16, wherein at least one of the first stabilizing layer and the second stabilizing layer has a thickness of greater than zero and less than or equal to 10 nm.

18. The coated article of claim 15 wherein the base layer comprises a first film comprising tin oxide in direct contact with the portion of the first surface.

19. The coated article of claim 15, wherein at least one of the first stabilizing layer and the second stabilizing layer comprises zinc stannate.

20. A method of forming a coated article comprising:
providing a substrate having a first surface and a second surface; and
applying a coating over at least a portion of the first surface, the coating comprising:
a base layer over at least a portion of the first surface;
a first protective layer over at least a portion of the base layer;
an optional first stabilizing layer over at least a portion of the first protective layer;
a transparent conductive oxide layer over the first stabilizing layer or the first protective layer;
an optional second stabilizing layer positioned over at least a portion of the transparent conductive oxide layer; and
a second protective layer over at least a portion of the second stabilizing layer or the transparent conductive oxide layer,
wherein at least one of the first stabilizing layer and the second stabilizing layer comprises zinc oxide, tin oxide, or a combination thereof.
